(19) United States
(12) Patent Application Publication
(10) Pub. No.: US 2025/0212375 A1
(43) Pub. Date: Jun. 26, 2025

(54) JOINING WORK MACHINE

(71) Applicant: FUJI CORPORATION, Chiryu (JP)

(72) Inventor: Hiromitsu OKA, Toyoake-shi (JP)

(73) Assignee: FUJI CORPORATION, Chiryu (JP)

(21) Appl. No.: 18/849,621

(22) PCT Filed: Apr. 21, 2022
(86) PCT No.: PCT/JP2022/018359

§ 371 Date: Sep. 23, 2024

(51) Int. Cl. H05K 13/04; B23K 1/005; B23K 26/035; B23K 101/42

(52) U.S. Cl. CPC H05K 13/041; B23K 1/0056; B23K 26/035; H05K 13/0469; B23K 2101/42

(57) ABSTRACT

A joining work machine includes a work head including a component mounting tool configured to pick up a component and mount the component on a workpiece by being lifted and lowered along a lifting-and-lowering axis, the work head being configured to be driven in a horizontal direction by a horizontal drive mechanism, and a laser light irradiation section provided in the work head or the horizontal drive mechanism and configured to apply laser light for heating a joining material that generates a predetermined joining force by being applied to at least one of contact surfaces of the component and the workpiece that are in contact with each other and being heated, toward any one of the joining material, the component, and the workpiece from a direction inclined with respect to the lifting-and-lowering axis.

### TECHNICAL FIELD

The present description relates to a joining work machine that joins a component to a workpiece.

### BACKGROUND ART

A technique for mass-producing a board product including an electronic circuit by joining a component serving as a circuit element to a board on which a circuit pattern is formed is widely used. In a board production line applied to this type of production application, a line configuration including a solder printer that prints solder as a joining material on a board, a component mounter that mounts a component on the board, and a reflow machine that heats the solder to ensure a predetermined joining force is adopted. Further, there is a line configuration in which the solder coats an electrode side of the component instead of being printed on the board, or a line configuration in which a conductive paste is used instead of the solder. In addition, when a contact surface to be joined is a part other than a conductive part, a resin material or an adhesive is used as the joining material, and in many cases, heating is required to ensure the predetermined joining force. Technical examples regarding such joining of the component are disclosed in Patent Literatures 1 to 5.

Patent Literature 1 discloses a component mounter that heats a connection end of an electronic component picked up by a suction nozzle with infrared laser light, lowers the suction nozzle toward a mounting board coated with solder in advance, and fixes the solder while bringing the electronic component into contact with the board. Patent Literature 2 discloses a laser soldering device in which conveyance means for conveying a component to a soldering position and laser heating means for performing preheating of the component and main heating of solder melting are integrally formed. The laser light emitted by the laser heating means reaches the electric component via an optical fiber and a lens in the conveyance means. Patent Literature 3 discloses a component mounter that indirectly heats a component by heating a suction nozzle with laser light applied via a half-silvered mirror.

Patent Literature 4 discloses an automatic mounting device including a conveyance placement device that conveys an electronic component and places the electronic component on a printed circuit board, and a pressing and heating device that performs soldering while pressing the electronic component after the conveyance placement device is separated. Patent Literature 5 discloses a component mounter including a YAG laser device that is provided in a tape feeder and heats a component accommodated in a pocket of the tape feeder, and component disposition means for placing the heated component on a board.

### PATENT LITERATURE

Patent Literature 1: JP-A-2000-13098

Patent Literature 2: JP-A-S60-162574

Patent Literature 3: JP-A-2000-59098

Patent Literature 4: JP-A-S61-224395

Patent Literature 5: JP-A-2014-22383

### BRIEF SUMMARY

### Technical Problem

The technical examples of Patent Literatures 1 to 5 have the following issues. That is, Patent Literature 1 does not disclose a specific configuration in which the heating is performed using the infrared laser light. In addition, in Patent Literatures 2, 3, and 5, there is a concern that the heating efficiency may decrease due to attenuation of the laser light, a loss of a heat quantity caused by heating a part other than a necessary range, a time lag from the heating to the joining, and the like. Further, in Patent Literatures 2 to 4, a device configuration for the heating tends to be complicated, and there is a concern that a device cost increases.

Although the technical examples of Patent Literatures 1 to 5 are all techniques for heating the solder, the joining material is not limited to the solder as described above. Furthermore, the joining work machine is not limited to having a configuration in which an electric component is joined to the board on which the circuit pattern is formed, and has, for example, a configuration in which a mechanical component is joined to various workpieces.

Therefore, an object of the present description is to provide a joining work machine capable of efficiently heating a joining material while suppressing an increase in device cost with a simple configuration.

### Solution to Problem

The present description discloses a joining work machine including: a work head including a component mounting tool configured to pick up a component and mount the component on a workpiece by being lifted and lowered along a lifting-and-lowering axis, the work head being configured to be driven in a horizontal direction by a horizontal drive mechanism; and a laser light irradiation section provided in the work head or the horizontal drive mechanism and configured to apply laser light for heating a joining material that generates a predetermined joining force by being applied to one of contact surfaces of the component and the workpiece that are in contact with each other and being heated, toward any one of the joining material, the component, and the workpiece from a direction inclined with respect to the lifting-and-lowering axis.

### Advantageous Effects

In the joining work machine disclosed in the present description, the laser light irradiation section configured to apply the laser light toward any one of the joining material, the component, and the workpiece from the direction inclined with respect to the lifting-and-lowering axis is provided in the work head or the horizontal drive mechanism. Accordingly, by applying the laser light toward any one of the joining material, the component, and the workpiece, the loss of the heat quantity caused by heating the part other than the necessary range is suppressed, an attenuation amount of the laser light is small, and the joining material can be efficiently heated. Furthermore, since the laser light irradiation section need only be added to the work head or the horizontal drive mechanism having a general configuration, it is possible to suppress the increase in device cost with a simple configuration.

### BRIEF DESCRIPTION OF DRAWINGS

FIG. 1 is a plan view schematically illustrating an overall configuration of a component mounter as a first embodiment of a joining work machine.

FIG. 2 is a perspective view of a nozzle tool provided in a mounting head (work head).

FIG. 3 is a perspective view of the mounting head (work head) provided with a laser light irradiation section.

FIG. 4 is a view of the mounting head and the laser light irradiation section as viewed from below.

FIG. 5 is a side view illustrating an operation of the laser light irradiation section when a laser light source and a suction nozzle are located at a lifting position.

FIG. 6 is a side view illustrating an operation of the laser light irradiation section when the laser light source and the suction nozzle are located at a lowering position.

FIG. 7 is a side view illustrating an operation of the laser light irradiation section when the laser light source is located at the lowering position and the suction nozzle is located at the lifting position.

FIG. 8 is a side view schematically illustrating a configuration of a laser light irradiation section of a third embodiment.

FIG. 9 is a view of a mounting head and a laser light irradiation section as viewed from below in a fourth embodiment.

### DESCRIPTION OF EMBODIMENTS

### 1. Overall Configuration of Component Mounter 1 of First Embodiment

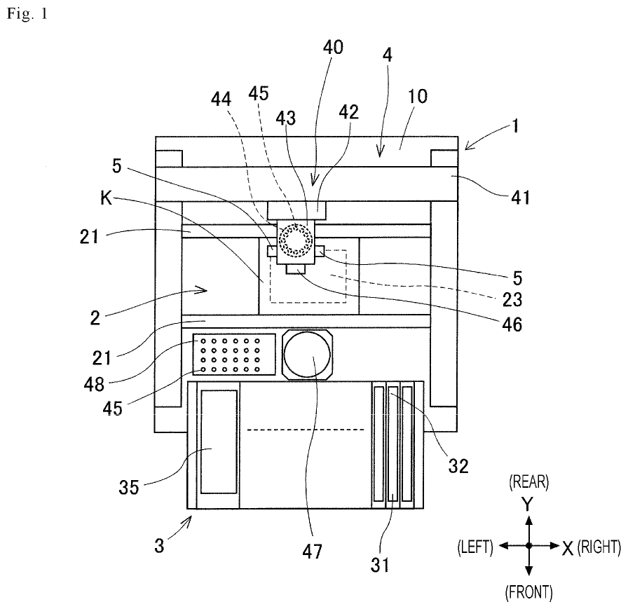

First, an overall configuration of component mounter 1 as a first embodiment of a joining work machine will be described with reference to FIG. 1. Component mounter 1 repeatedly performs joining work of mounting and joining a component to a workpiece. In the first embodiment, the component is a circuit element of an electronic circuit, and the workpiece is board K on which a circuit pattern of the electronic circuit is formed. Component mounter 1 uses, for example, a non-conductive resin material as a joining material that generates a predetermined joining force by being heated. A direction from a left side toward a right side on a drawing surface in FIG. 1 in which board K is conveyed is an X-axis direction, and a direction from a lower side (front side) toward an upper side (rear side) on the drawing surface is a Y-axis direction. Component mounter 1 includes board conveyance device 2, component supply device 3, component transfer joining device 4, and laser light irradiation section 5.

Board conveyance device 2 includes pair of guide rails 21, a pair of conveyance belts (not illustrated), clamp mechanism 23, and the like. Pair of guide rails 21 extends in the X-axis direction across the center of an upper surface of base 10, and is assembled to base 10 parallel to each other. The pair of conveyance belts rotate along guide rails 21 in a state where two parallel sides of board K are placed, and carry in board K to a work performing position in the vicinity of the center of base 10. Clamp mechanism 23 pushes up carried-in board K, clamps board K with guide rails 21, and positions board K.

Component supply device 3 is disposed at a front part of base 10. Component supply device 3 includes multiple tape feeders 31 and resin material supply section 35. Tape feeders 31 have a flat shape elongated in the front-rear direction (Y-axis direction) and thin in the left-right direction (X-axis direction), and are arranged in the X-axis direction. Each tape feeder 31 feeds a carrier tape in which multiple components are accommodated in a row toward supply position 32 near a rear end. The carrier tape supplies the component such that the component can be picked up at supply position 32.

Resin material supply section 35 is disposed on a left side of tape feeder 31 and supplies a resin material as the joining material. Resin material supply section 35 includes a supply tray, a replenishment mechanism, and a heat retaining section (which are not illustrated). The supply tray is formed in a flat bottom shape opening upward, and holds a liquid resin material therein. It is preferable that the supply tray has a mechanism that flattens a liquid level of the resin material as necessary. The replenishment mechanism replenishes the inside of the supply tray with the resin material when the resin material is consumed and decreased. The heat retaining section is disposed on a lower side of the supply tray, and applies heat to the resin material inside the supply tray to prevent solidification due to a decrease in temperature.

The resin material is cooled and solidified after being heated to be equal to or higher than a predetermined temperature, thereby generating the predetermined joining force. The resin material is applied to at least one of contact surfaces of the component and board K that are in contact with each other. In the first embodiment, a lower surface (contact surface) of the component is coated with the resin material by resin material supply section 35. The present configuration is not limited thereto, and the resin material may be applied to the contact surface on a side of board K to which the component is joined. Examples of the predetermined temperature for heating the resin material include about 100° C. Examples of the coating thickness of the resin material include about 10 μm.

A material of the resin material is selected in consideration of a material of the component or board K. The predetermined temperature and the coating thickness of the resin material are appropriately set in accordance with the material and the properties of the resin material. Instead of the resin material, an adhesive of a type in which the predetermined joining force is generated by being heated to be equal to or higher than the predetermined temperature may be used. In addition, resin material supply section 35 may be configured to coat the component with the resin material by using a brush or may be configured to spray the resin material from a spray nozzle toward the component. Further, a configuration may be adopted in which the component supplied from tape feeder 31 or the component supply unit of another type is coated with the resin material in advance, and resin material supply section 35 is omitted.

Component transfer joining device 4 performs pickup and mounting of the component and the joining work. Component transfer joining device 4 includes Y-axis moving body 41, X-axis moving body 42, mounting head 43, nozzle tool 44, multiple suction nozzles 45 corresponding to a component mounting tool, board recognition camera 46, component recognition camera 47, and nozzle station 48. Mounting head 43 is provided with laser light irradiation section 5 for performing the joining work (details will be described later).

Y-axis moving body 41 is formed of a member elongated in the X-axis direction, and is driven by a Y-direction drive mechanism (not illustrated) to move in the Y-axis direction. X-axis moving body 42 is mounted on Y-axis moving body 41 and is driven by an X-direction drive mechanism (not illustrated) to move in the X-axis direction. Mounting head 43 is attached to a clamp mechanism (not illustrated) provided on a front surface of X-axis moving body 42, and moves in two horizontal directions together with X-axis moving body 42. Y-axis moving body 41, the Y-direction drive mechanism, X-axis moving body 42, and the X-direction drive mechanism constitute horizontal drive mechanism 40 that drives mounting head 43 in the horizontal direction. Mounting head 43 is one embodiment of a work head including a component mounting tool.

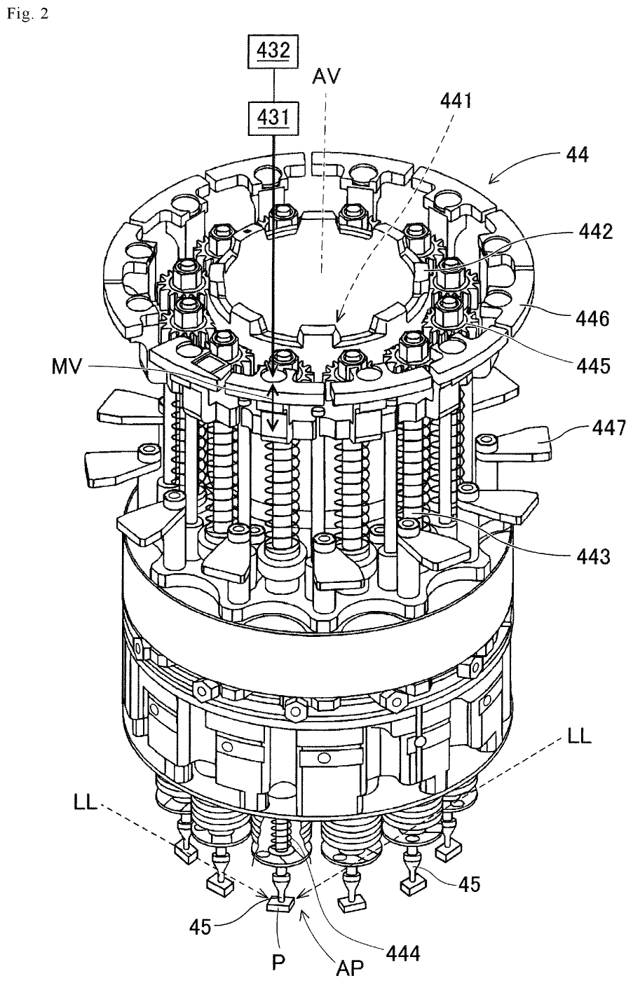

Nozzle tool 44 having a substantially cylindrical outer shape is provided on the lower side of mounting head 43. Nozzle tool 44 is formed as a rotating body that rotates about vertical central axis AV (see FIG. 2). Nozzle tool 44 includes multiple (twelve in the example of FIG. 1) suction nozzles 45 that revolve around vertical central axis AV. Suction nozzle 45 is selectively supplied with negative pressure air and positive pressure air from an air supply system (not illustrated). Accordingly, suction nozzle 45 performs a pickup operation of picking up the component from tape feeder 31 and a mounting operation of mounting the component on board K.

Here, “mounting” means placing the component on board K, and “joining” means ensuring the predetermined joining force between the component and board K. That is, the joining force is not ensured only by mounting the component. Suction nozzle 45 is one embodiment of a component mounting tool configured to pick up a component and mount the component on a workpiece by being lifted and lowered along a lifting-and-lowering axis. As the component mounting tool, a mounting tool of a type including a chuck for clamping the component or a mounting tool of another type may be used. A detailed configuration of nozzle tool 44 will be described later.

Board recognition camera 46 may be provided on a front side of mounting head 43 and may be provided on a lower side of X-axis moving body 42. Board recognition camera 46 is disposed such that an optical axis is directed downward, and captures an image of a position fiducial mark attached to board K from above. The acquired image data is subjected to image processing, so that the work performing position of board K is accurately obtained. Examples of board recognition camera 46 include a digital imaging device including an imaging element such as a charge coupled device (CCD) or a complementary metal oxide semiconductor (CMOS).

Component recognition camera 47 is provided on base 10 between board conveyance device 2 and component supply device 3. Component recognition camera 47 is disposed such that an optical axis is directed upward. Component recognition camera 47 captures an image of the component held by suction nozzle 45 from below to recognize the component while mounting head 43 moves to board K. As a result, it is determined whether a coating state of the resin material that coats the component is appropriate, and a position and an orientation of the component with respect to suction nozzle 45 are detected and reflected in the mounting work. Examples of component recognition camera 47 include a digital imaging device including an imaging element such as CCD or CMOS.

Nozzle station 48 is provided on a left side of component recognition camera 47. Nozzle station 48 holds multiple suction nozzles 45 in an exchangeable manner. For example, multiple types having different nozzle diameters are prepared as multiple suction nozzles 45, and suction nozzles 45 are appropriately exchanged in accordance with various components having different sizes. When an error rate of the pickup operation and the mounting operation of specific suction nozzle 45 increases, suction nozzle 45 may be exchanged with another suction nozzle 45 of the same type. Mounting head 43 has a function of moving to nozzle station 48 and automatically exchanging suction nozzle 45. The present configuration is not limited thereto, and suction nozzle 45 may be manually exchanged. Further, mounting head 43 may have a function of automatically exchanging nozzle tool 44, or nozzle tool 44 may be manually exchanged.

Component transfer joining device 4 can repeatedly perform multiple joining cycles on positioned board K. In the joining cycle, first, mounting head 43 moves above tape feeder 31, and suction nozzles 45 are subsequently lowered and lifted to perform the pickup operation of the component. Next, mounting head 43 moves above resin material supply section 35, suction nozzles 45 are subsequently lowered and lifted, and the lower surface of the component held by suction nozzle 45 is immersed and coated with the resin material. Next, mounting head 43 moves above component recognition camera 47, and component recognition camera 47 captures the image. Next, mounting head 43 moves above board K, and suction nozzles 45 are subsequently lowered and lifted to perform the mounting operation of the component.

While mounting head 43 moves above board K from resin material supply section 35, and while suction nozzle 45 is lowered and lifted above board K, laser light irradiation section 5 operates in at least a part of time periods. As a result, the joining work is performed by the resin material being heated to be equal to or higher than the predetermined temperature, and then cooled and solidified. Mounting head 43 having finished the mounting operation of the component moves toward tape feeder 31 again. The joining cycle is a generic term of the series of operations described above.

### 2. Nozzle Tool 44

Next, a detailed configuration of nozzle tool 44 including twelve suction nozzles 45 will be described with reference to FIG. 2. Nozzle tool 44 includes tool main body portion 441 and cylindrical gear 442. Further, nozzle tool 44 includes twelve sets of nozzle holders 443, elastic bodies 444, θ-axis gears 445, locking pieces 446, and valve operation pieces 447 disposed at equal angular intervals around vertical central axis AV.

Tool main body portion 441 is supported on the lower side of mounting head 43, and a part of an outer shape thereof is omitted in FIG. 2. Tool main body portion 441 is driven by an R-axis drive mechanism (not illustrated) provided in mounting head 43 and rotates about vertical central axis AV. Accordingly, entire nozzle tool 44 rotates. Twelve sets of nozzle holders 443 are disposed at equal angular intervals at positions at equal distances from vertical central axis AV of tool main body portion 441.

Nozzle holder 443 extends in the up-down direction and is supported by tool main body portion 441 in a lifting-and-lowering enabled manner. Suction nozzle 45 is attached to a lower side of nozzle holder 443 via elastic body 444 (FIG. 2 illustrates one in a partial cross section). Accordingly, when nozzle tool 44 rotates, the twelve suction nozzles 45 revolve around vertical central axis AV. Examples of elastic body 444 include a coil spring. Meanwhile, θ-axis gear 445 is provided on an upper side of nozzle holder 443, and locking piece 446 is provided on radially outer side of θ-axis gear 445. Further, valve operation piece 447 is provided corresponding to each nozzle holder 443.

Cylindrical gear 442 is disposed inside twelve θ-axis gears 445. Cylindrical gear 442 has large-diameter gears (not illustrated) that mesh with twelve θ-axis gears 445 on its outer peripheral surface. Cylindrical gear 442 is driven by a θ-axis drive mechanism (not illustrated) provided in mounting head 43 and rotates around vertical central axis AV. Accordingly, cylindrical gear 442 collectively rotates twelve sets of nozzle holders 443 and suction nozzles 45. Valve operation piece 447 opens and closes an air flow path (not illustrated), and selectively switches between negative pressure air and positive pressure air to be supplied to suction nozzle 45.

Locking piece 446 is driven by Z-axis drive mechanism 431 provided in mounting head 43 to be lifted and lowered (see arrow MV in FIG. 2). By the lifting and lowering operation of locking piece 446, nozzle holder 443 is lifted and lowered in a range from the lifting position to the lowering position along the lifting-and-lowering axis extending in a vertical direction. Further, suction nozzle 45 is lifted and lowered via elastic body 444. However, Z-axis drive mechanism 431 is provided at one or several limited positions on a revolution trajectory of suction nozzle 45, and the lifting-and-lowering axis is set at the position. Hereinafter, the position at which the lifting-and-lowering axis is set is referred to as lifting-and-lowering enabled position AP.

Lifting-and-lowering enabled position AP is determined by the disposition of Z-axis drive mechanism 431 on mounting head 43. Accordingly, even when nozzle tool 44 rotates, lifting-and-lowering enabled position AP does not move, and only suction nozzle 45 that has entered lifting-and-lowering enabled position AP can be lifted and lowered. The lowering position at which Z-axis drive mechanism 431 lowers nozzle holder 443 via locking piece 446 and a stay time during which nozzle holder 443 stays at the lowering position are set by setting section 432. Setting section 432 is achieved by, for example, software that controls the operation of Z-axis drive mechanism 431.

When suction nozzle 45 that has picked up component P enters lifting-and-lowering enabled position AP and is lowered toward board K, nozzle holder 443 and suction nozzle 45 are first lowered in conjunction with each other. When component P comes into contact with board K, the lowering of suction nozzle 45 is stopped, and only the lowering of nozzle holder 443 is continued to the lowering position. As a result, the compression of elastic body 444 is started, a compression amount further increases, and a compressive force gradually increases. The compressive force acts on component P from elastic body 444 via suction nozzle 45, to be a downward pressing force.

That is, suction nozzle 45 is attached to mounting head 43 via elastic body 444, and presses component P against board K with the pressing force generated by the compression of elastic body 444. In this way, a joining state is stabilized by performing the joining work in a state where component P is pressed against board K. Thereafter, when nozzle holder 443 is lifted from the lowering position, the compression amount of elastic body 444 decreases, and the compressive force gradually decreases. When suction nozzle 45 is separated from component P mounted on board K, the compressive force disappears.

Here, setting section 432 sets the lowering position at which Z-axis drive mechanism 431 lowers nozzle holder 443 to be changeable. When the lowering position of nozzle holder 443 is set to be low, the compression amount of the elastic body 444 increases, and the pressing force when component P is pressed against board K increases. Conversely, when the lowering position of nozzle holder 443 is set to be high, the compression amount of the elastic body 444 decreases, and the pressing force when component P is pressed against board K decreases. That is, setting section 432 can variably set the pressing force of suction nozzle 45 when suction nozzle 45 presses component P against board K. Setting section 432 may change the pressing force in accordance with at least one of a type of component P and a type of the joining material. For example, a recommended value may be determined for the pressing force during the joining work depending on the type of joining material S, and setting section 432 sets the pressing force corresponding to the recommended value.

Further, setting section 432 sets the stay time during which nozzle holder 443 stays at the lowering position to be changeable. That is, setting section 432 can set an appropriate stay time based on a method of performing the joining work or an expected heating required time. Furthermore, setting section 432 may change the stay time in accordance with at least one of the type of component P and the type of the joining material.

### 3. Laser Light Irradiation Section 5

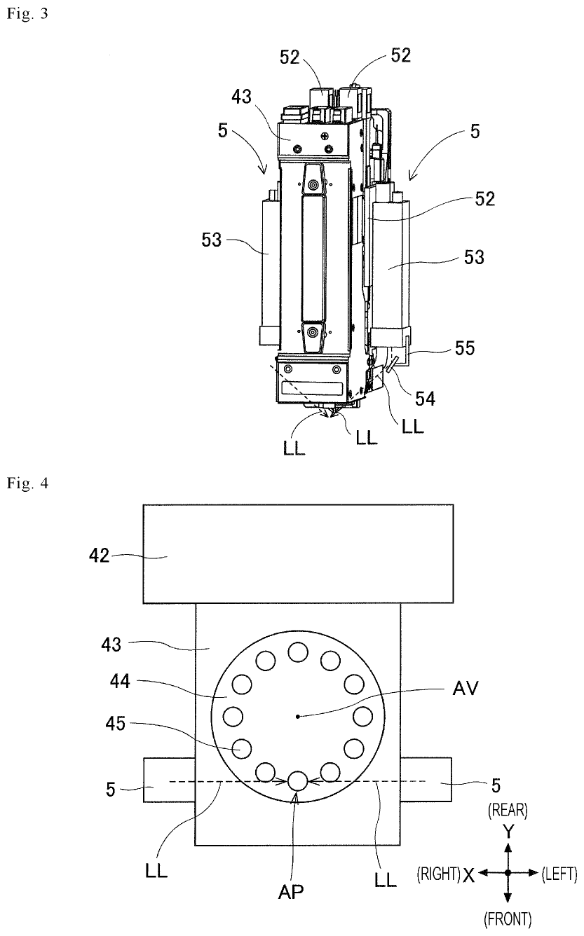

Next, a detailed configuration and a function of laser light irradiation section 5 will be described with reference to FIGS. 3 to 7. As illustrated in FIG. 3, laser light irradiation section 5 is provided on each of a right side and a left side of mounting head 43. Two laser light irradiation sections 5 are disposed within a range of a length dimension of X-axis moving body 42 in the left-right direction, and do not restrict the movement of X-axis moving body 42 and mounting head 43 in the X-axis direction. Laser light irradiation section 5 may be provided in X-axis moving body 42 that moves integrally with mounting head 43 among the elements of horizontal drive mechanism 40. Laser light irradiation section 5 applies laser light LL for heating joining material S toward any one of joining material S, component P, or board K from a direction inclined with respect to the lifting-and-lowering axis. Laser light irradiation section 5 includes optical switching mechanism 52, laser light source 53, and reflection mirror 54.

Optical switching mechanism 52 is provided in contact with an upper surface and a side surface (right side surface or left side surface) of mounting head 43. Optical switching mechanism 52 is a section that switches an irradiation position at which laser light LL is applied. Optical switching mechanism 52 switches the irradiation position by changing the positions of laser light source 53 that emits laser light LL and reflection mirror 54 that reflects laser light LL with respect to mounting head 43.

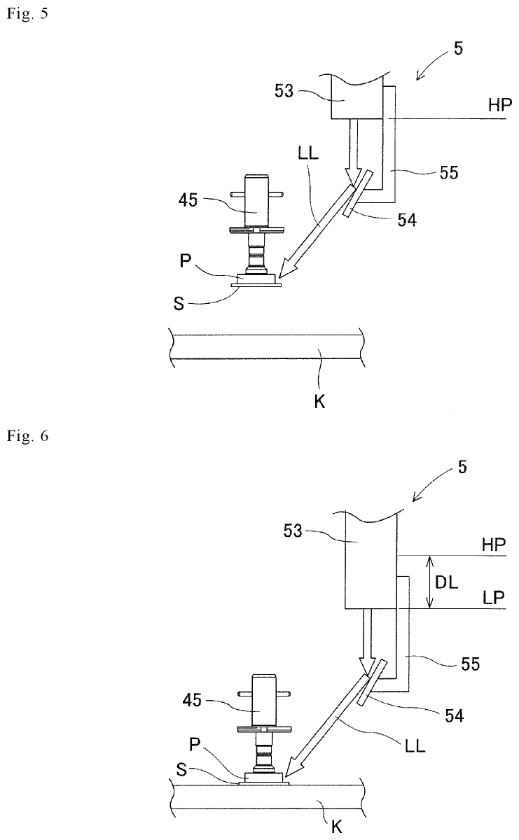

Specifically, optical switching mechanism 52 drives laser light source 53 and reflection mirror 54 to be lifted and lowered, and switches height positions thereof between lifting position HP and lowering position LP (see FIGS. 5 to 7). In the first embodiment, a servo motor is used as optical switching mechanism 52. In a configuration in which fine adjustment to be described later is performed, optical switching mechanism 52 using the servo motor has a function of finely adjusting the height positions of laser light source 53 and reflection mirror 54 in addition to a function of switching the height positions between lifting position HP and lowering position LP. The height position of laser light source 53 may be fixed, and optical switching mechanism 52 may drive only reflection mirror 54 to be lifted and lowered. As optical switching mechanism 52, a mechanism other than the servo motor, for example, a linear motor or an air operation mechanism may be used.

Laser light source 53 is formed in a vertically long rectangular parallelepiped shape, and is supported by optical switching mechanism 52 in a lifting-and-lowering enabled manner. Laser light source 53 emits laser light LL downward parallel to the lifting-and-lowering axis. A type of laser light LL is suitable for heating the joining material, and an intensity of laser light LL is, for example, class 4, which is the highest in the JIS standards. Accordingly, it is possible to heat joining material S together with component P to be equal to or higher than the predetermined temperature by applying laser light LL for a short time on the order of several tens of milliseconds.

Reflection mirror 54 is disposed below laser light source 53 using support member 55, and is lifted and lowered integrally with laser light source 53. Reflection mirror 54 reflects laser light LL emitted downward from laser light source 53 in an oblique down direction inclined with respect to the lifting-and-lowering axis. Accordingly, laser light LL reaches component P held by suction nozzle 45. Laser light LL may be applied to entire component P or may be applied to a part of component P. For example, in a case of component P in which the entire lower surface is coated with joining material S, laser light LL may be applied to entire component P to heat entire joining material S. On the other hand, in a case of component P in which the electrode is coated with the solder as joining material S or the conductive paste, laser light LL may be applied to a position close to the electrode which is a part of component P, to efficiently heat the electrode and joining material S. In addition, in a case where a mounting angle is revolved by 90° when component P is mounted on board K, optical switching mechanism 52 may operate to apply laser light LL to the position of the electrode of component P to efficiently heat the electrode.

Instead of reflection mirror 54, a prism or a glass refractive plate that refracts downward laser light LL in the oblique down direction inclined with respect to the lifting-and-lowering axis may be used. Reflection mirror 54, the prism, and the glass refractive plate are one embodiment of an optical member that reflects or refracts laser light LL emitted downward in the direction inclined with respect to the lifting-and-lowering axis. Laser light irradiation section 5 may include a light path regulating member that regulates laser light LL from reaching board K. The light path regulating member is formed of, for example, a metal plate through which laser light LL does not pass, and is disposed obliquely below component P held by suction nozzle 45 at lifting-and-lowering enabled position AP. By using the light path regulating member, board K which is weak to laser light LL can be protected.

In the first embodiment, as illustrated in FIG. 4, lifting-and-lowering enabled position AP is set at a position corresponding to a front part of nozzle tool 44. As illustrated, two sets of laser light irradiation sections 5 apply laser light LL toward component P held by suction nozzle 45 at lifting-and-lowering enabled position AP. That is, two sets of laser light irradiation sections 5 are provided in common to multiple suction nozzles 45 that selectively enter lifting-and-lowering enabled position AP. The target to which laser light LL is applied is not limited to suction nozzle 45 at lifting-and-lowering enabled position AP, and may be set to, for example, suction nozzle 45 located immediately before lifting-and-lowering enabled position AP.

In addition, multiple laser light irradiation sections 5 are provided for one lifting-and-lowering axis (lifting-and-lowering enabled position AP). Accordingly, two beams of laser light LL are applied to one component P at lifting-and-lowering enabled position AP from different directions, so that high heating efficiency and a sufficient heat quantity can be easily ensured. In two sets of laser light irradiation sections 5, the lifting and lowering of two laser light sources 53 are controlled in synchronization with each other, and irradiation time periods of two laser light sources 53 are controlled in synchronization with each other.

As illustrated in FIG. 5, when laser light source 53 is located at lifting position HP, laser light LL is applied to component P held by suction nozzle 45 at the lifting position. Further, as illustrated in FIG. 6, when laser light source 53 is located at lowering position LP which is lower than lifting position HP by lowering distance DL, laser light LL is applied to component P pressed against board K by suction nozzle 45 lowered to the lowering position. Lowering distance DL is set to be substantially equal to a difference height between the lifting position and the lowering position of suction nozzle 45.

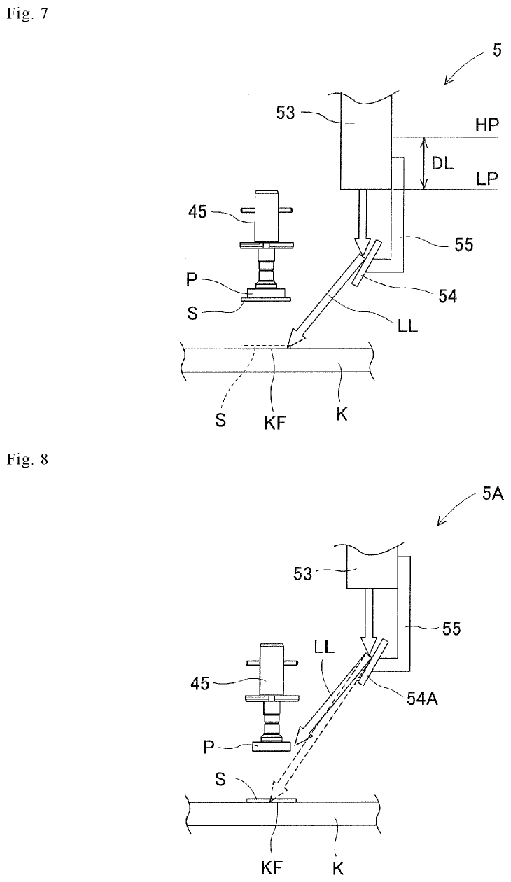

Further, as illustrated in FIG. 7, when laser light source 53 is located at lowering position LP and suction nozzle 45 is located at the lifting position, laser light LL is applied to contact surface KF of board K to which component P is to be joined. When contact surface KF of board K is coated with joining material S, laser light LL is applied to joining material S. In this way, optical switching mechanism 52 can switch the irradiation position of laser light LL by changing, in the up-down direction, the positions of laser light source 53 and reflection mirror 54 with respect to mounting head 43.

Lifting-and-lowering enabled position AP of the nozzle tool (not illustrated) including four medium-size suction nozzles is set to the same position as nozzle tool 44 including twelve suction nozzles 45. Accordingly, when the nozzle tool including the four medium-size suction nozzles is provided in mounting head 43, laser light irradiation section 5 can perform the same operation as the operation for nozzle tool 44. On the other hand, lifting-and-lowering enabled position AP of a nozzle tool (not illustrated) including one large-size suction nozzle is set to overlap vertical central axis AV, and is different from that of nozzle tool 44. In order to handle this case, a configuration can be adopted in which optical switching mechanism 52 has a function of changing, in the front-rear direction, the positions of laser light source 53 and reflection mirror 54 with respect to mounting head 43.

A configuration can be adopted in which optical switching mechanism 52 also has a function of finely adjusting the irradiation position of laser light LL. For example, when a size or a shape of component P changes due to a difference in the type of component P, the irradiation position at which the heating can be efficiently performed changes, and thus optical switching mechanism 52 finely adjusts the irradiation position of laser light LL. For example, regarding two types of components having the same lower surface shape and different heights, optical switching mechanism 52 finely adjusts the irradiation position of the component having a relatively high height to be higher, and finely adjusts the irradiation position of the component having a relatively low height to be lower. When there is a shape error such as warpage in board K, the height position of component P mounted on board K varies, and optical switching mechanism 52 finely adjusts the irradiation position in accordance with the actual height position of component P.

### 4. Operation of Component Mounter 1

Next, the operation of component mounter 1 will be described focusing mainly on the joining work of component P via laser light irradiation section 5. In the operation of component mounter 1, multiple irradiation patterns of laser light irradiation section 5 can be selected in accordance with the irradiation position or the irradiation time period of laser light LL, whether joining material S is applied to component P or board K, and the like. Hereinafter, the following irradiation patterns (1) to (4) will be described.

### (1) Basic Irradiation Pattern

Laser light irradiation section 5 applies laser light LL at a timing including a time period during which suction nozzle 45 brings component P into contact with board K with laser light source 53 at lowering position LP (see FIG. 6). Specifically, laser light irradiation section 5 applies laser light LL in a state where suction nozzle 45 presses component P against board K with the pressing force set by setting section 432. In this case, since component P, joining material S, and board K are stacked in the up-down direction, the irradiation position of laser light LL is limited to component P. Joining material S may be applied to either component P or board K.

In the basic irradiation pattern, laser light irradiation section 5 applies laser light LL each time nozzle tool 44 of the rotating body rotates and twelve suction nozzles 45 subsequently perform the mounting operation. Laser light irradiation section 5 indirectly heats joining material S to be equal to or higher than the predetermined temperature via component P by applying laser light LL toward component P. Thereafter, the temperature of joining material S decreases, joining material S is solidified, and the joining work is finished.

When there is a concern that the irradiation time is insufficient, setting section 432 sets the stay time during which nozzle holder 443 stays at the lowering position to be longer than that in a normal state, and ensures a sufficient irradiation time. In addition, laser light irradiation section 5 may apply laser light LL in a time period from immediately before the lowering of suction nozzle 45 is started to the middle of the lowering operation (see FIG. 7). Accordingly, contact surface KF can be preheated by setting the irradiation position of laser light LL to contact surface KF of board K. However, since board K has a large thermal capacity, it is difficult to heat board K to a predetermined temperature, and thus the operation of heating only board K without heating component P cannot be adopted.

### (2) Pre-Contact Heating Irradiation Pattern

Laser light irradiation section 5 applies laser light LL in a time period before suction nozzle 45 brings component P into contact with board K with laser light source 53 at lifting position HP (see FIG. 5). The irradiation position of laser light LL is limited to component P held by suction nozzle 45 at the lifting position. Joining material S is applied to component P. The time period before suction nozzle 45 brings component P into contact with board K means at least a part of a time period from when suction nozzle 45 picks up component P from tape feeder 31 to when suction nozzle 45 moves to board K and is lowered.

In the pre-contact heating irradiation pattern, since nozzle tool 44 of the rotating body rotates, laser light irradiation section 5 subsequently applies laser light LL toward all components P picked up by twelve suction nozzles 45. Accordingly, joining material S that coats the lower surface of component P is heated to be equal to or higher than the predetermined temperature before the contact with board K. Thereafter, component P is mounted on board K, the temperature of joining material S decreases, joining material S is solidified, and the joining work is finished.

### (3) Heat Quantity Accumulation Irradiation Pattern

Laser light irradiation section 5 applies laser light LL in a time period before suction nozzle 45 brings component P into contact with board K with laser light source 53 at lifting position HP (see FIG. 5). The irradiation position of laser light LL is limited to component P held by suction nozzle 45 at the lifting position. Unlike (2), joining material S is applied to contact surface KF of board K. Accordingly, laser light irradiation section 5 cannot heat joining material S even when laser light LL is applied toward component P, but can accumulate the heat quantity in component P.

In the heat quantity accumulation irradiation pattern, since nozzle tool 44 of the rotating body rotates, laser light irradiation section 5 subsequently applies laser light LL toward all components P picked up by twelve suction nozzles 45. Accordingly, each of components P accumulates the heat quantity and reaches a temperature equal to or higher than the predetermined temperature. After suction nozzle 45 brings component P into contact with board K, joining material S applied to contact surface KF of board K is heated with the heat quantity accumulated in component P to be equal to or higher than the predetermined temperature. Thereafter, the temperature of joining material S decreases, joining material S is solidified, and the joining work is finished.

### (4) Combined Irradiation Pattern

The above-described (1) and (2) can be used in combination. However, in combination, laser light irradiation section 5 lifts and lowers laser light source 53 by optical switching mechanism 52. Accordingly, even when the heating of joining material S in the pre-contact heating irradiation pattern of (2) is insufficient, it is possible to stabilize the joining work by performing additional heating with the basic irradiation pattern of (1).

Furthermore, the above-described (1) and (3) can be used in combination. However, in combination, laser light irradiation section 5 lifts and lowers laser light source 53 by optical switching mechanism 52. Accordingly, even when the accumulated heat quantity of component P in the heat quantity accumulation irradiation pattern of (3) is insufficient, it is possible to stabilize the joining work by performing additional heating with the basic irradiation pattern of (1).

In the combination of the two cases described above, optical switching mechanism 52 may lower laser light source 53 and reflection mirror 54 in synchronization with each other to interlock with the lowering of suction nozzle 45 that picks up component P. In this operation form, suction nozzle 45, laser light source 53, and reflection mirror 54 are lowered in conjunction with each other, and laser light LL is applied to component P during the time period of the lowering. Accordingly, it is possible to increase an effective irradiation time in which laser light LL is applied to component P and to stabilize the joining work.

As can be seen from the above description, the combined irradiation pattern of (4) is effective for large-size component P having a large thermal capacity. The thermal capacity of component P is substantially determined in accordance with the size of component P, and the irradiation pattern may be changed in accordance with the type of component P. Further, since the predetermined temperature to which the heating should be performed is determined in accordance with the material and the properties of joining material S, the irradiation pattern may be changed in accordance with the type of joining material S.

In component mounter 1 of the first embodiment, mounting head 43 is provided with laser light irradiation section 5 that applies laser light LL toward any one of joining material S, component P, and board K from the direction inclined with respect to the lifting-and-lowering axis. Accordingly, by applying laser light LL toward any one of joining material S, component P, and board K, the loss of the heat quantity caused by heating the part other than the necessary range is suppressed, an attenuation amount of laser light LL is small, and the joining material can be efficiently heated. Furthermore, since laser light irradiation section 5 need only be added to mounting head 43 or horizontal drive mechanism 40 having a general configuration, it is possible to suppress the increase in device cost with a simple configuration.

Further, laser light irradiation section 5 adopts a configuration in which laser light source 53 that emits laser light LL in the direction parallel to the lifting-and-lowering axis and reflection mirror 54 that reflects emitted laser light LL in the direction inclined with respect to the lifting-and-lowering axis are combined. Accordingly, mounting head 43 can be configured to be compact, and a movement range of mounting head 43 in the horizontal direction is not restricted. In addition, since laser light irradiation section 5 includes optical switching mechanism 52, multiple irradiation patterns for heating joining material S can be selectively performed, or multiple irradiation patterns can be used in combination. An aspect can be implemented in which reflection mirror 54 is omitted and laser light source 53 is inclined. However, in this aspect, since laser light source 53 protrudes to the right and left sides from X-axis moving body 42 and mounting head 43 is increased in size, the movement range of mounting head 43 in the left-right direction (X-axis direction) is easily restricted.

Further, in the related art, a dedicated heating device for heating the joining material is generally disposed in a previous process or a subsequent process of the component mounter, but the dedicated heating device is not necessary in component mounter 1 of the first embodiment. Accordingly, the line shortening and the space saving of a joining work line, the reduction in the line construction cost, and the like are achieved.

### 5. Component Mounter 1 of Second Embodiment

Next, a second embodiment using paste solder as the joining material will be described. In the second embodiment, the configuration itself of component mounter 1 is as described in the first embodiment. However, the solder as the joining material is printed on board K by a solder printer in the previous process. Further, tape feeder 31 of component supply device 3 supplies the component including the electrode on the lower surface, and resin material supply section 35 is stopped.

In the joining cycle of the second embodiment, first, mounting head 43 moves above tape feeder 31, and suction nozzles 45 are subsequently lowered and lifted to perform the pickup operation of the component. Next, mounting head 43 moves above component recognition camera 47, and component recognition camera 47 captures the image. Next, mounting head 43 moves above board K, and suction nozzles 45 are subsequently lowered and lifted to mount the component on the solder of board K. While mounting head 43 moves above board K, and while suction nozzle 45 is lowered and lifted above board K, laser light irradiation section 5 operates in at least a part of time periods. Accordingly, the solder is melted by applying laser light LL, and the solder is solidified by a decrease in temperature after the melting, and a good soldering state (joining state) in which the predetermined joining force is ensured is obtained.

In the second embodiment, component mounter 1 can selectively implement any one of the basic irradiation pattern of (1), the heat quantity accumulation irradiation pattern of (3), and the combined irradiation pattern of (1) and (3) described above even when the joining material is different. In the second embodiment, as in the first embodiment, the solder can be efficiently heated, and an increase in device cost can be suppressed with a simple configuration.

Further, in the related art, a reflow machine for melting the solder is required in a subsequent process of the component mounter that mounts the component, but the reflow machine is not necessary in the second embodiment. In addition, in component mounter 1 of the second embodiment, since the joining is finished to obtain a good soldering state, it is possible to eliminate an unstable state where the position of the component on the solder is shifted or the posture is inclined until board K is conveyed to the reflow machine.

### 6. Third Embodiment

Next, a third embodiment different from the first embodiment in a configuration of laser light irradiation section 5A will be described with reference to FIG. 8. In the third embodiment, in laser light irradiation section 5A, optical switching mechanism 52 is omitted, and the height position of laser light source 53 is fixed. Instead, an angle adjustment mechanism (not illustrated) for adjusting an inclination angle of reflection mirror 54A is provided.

At a first inclination angle of reflection mirror 54A illustrated in FIG. 8, laser light LL reflected by reflection mirror 54A is applied to component P held by suction nozzle 45 at the lifting position. When the inclination angle of reflection mirror 54A is adjusted to a second inclination angle closer to the vertical direction than the first inclination angle by the angle adjustment mechanism, a reflection direction of laser light LL is changed as indicated by a broken line, and laser light LL is applied to contact surface KF of board K or joining material S applied to the contact surface. In this case, when suction nozzle 45 is lowered to the lowering position, laser light LL indicated by a broken line is applied to component P pressed against board K. In the third embodiment, since the angle adjustment mechanism switches the irradiation position of laser light LL instead of optical switching mechanism 52, the same operations, actions, and effects as those of the first embodiment are obtained.

### 7. Fourth Embodiment

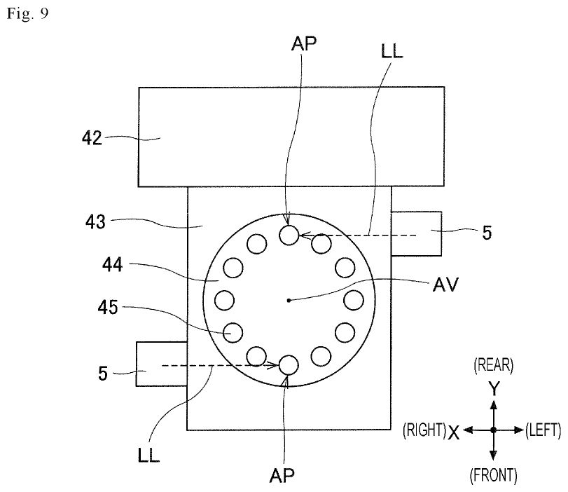

Next, a fourth embodiment different from the first embodiment in that lifting-and-lowering enabled positions AP are set at two positions and the disposition of laser light irradiation section 5 is different will be described with reference to FIG. 9. In the fourth embodiment, as illustrated in FIG. 9, lifting-and-lowering enabled positions AP at which suction nozzle 45 can be lifted and lowered are set at two positions corresponding to the front part and the rear part of nozzle tool 44.

First laser light irradiation section 5 that applies laser light LL toward lifting-and-lowering enabled position AP on the front part is provided on the right side of mounting head 43. Second laser light irradiation section 5 that applies laser light LL toward lifting-and-lowering enabled position AP on the rear part is provided on the left side of mounting head 43. In other words, laser light irradiation section 5 is provided corresponding to each of the multiple lifting-and-lowering axes (lifting-and-lowering enabled positions AP).

Operations, actions, and effects of the fourth embodiment are the same as those of the first embodiment except that the number of laser light irradiation sections 5 for one lifting-and-lowering enabled position AP is different. As in the first embodiment, two laser light irradiation sections 5 can be provided for one lifting-and-lowering axis (lifting-and-lowering enabled position AP), and a total of four laser light irradiation sections 5 can be provided for two lifting-and-lowering axes.

### 8. Application and Modification of Embodiment

In the first embodiment, suction nozzle 45 does not necessarily press component P against board K, and a different type of component mounting tool may simply place component P on contact surface KF of board K. In this case, in the basic irradiation pattern of (1), laser light irradiation section 5 applies laser light LL at the timing including the time period during which suction nozzle 45 brings component P into contact with board K. In addition, optical switching mechanism 52 of laser light irradiation section 5 may be omitted, laser light source 53 may be fixed to mounting head 43, laser light LL may be applied to component P pressed by suction nozzle 45 at the lowering position against board K, and only the basic irradiation pattern of (1) may be performed. Alternatively, laser light source 53 may be fixed, laser light LL may be applied to component P held by suction nozzle 45 at the lifting position, and the pre-contact heating irradiation pattern of (2) and the heat quantity accumulation irradiation pattern of (3) may be selectively performed.

Further, a configuration may be adopted in which mounting head 43 includes only one suction nozzle 45 without including nozzle tool 44 of the rotating body. Further, a configuration may be adopted in which mounting head 43 includes multiple suction nozzles 45 arranged in a row shape or a grid shape without including nozzle tool 44, and laser light irradiation section 5 is provided in common to multiple suction nozzles 45 in a relatively movable manner. In addition, the multiple aspects of laser light irradiation section 5 described above and the multiple aspects of the component mounting tool provided in mounting head 43 can be freely combined and implemented.

Further, as a first modification example of the second embodiment, a configuration can be adopted in which the conductive paste is used as the joining material, and a conductive paste supply section is provided at the position of resin material supply section 35. As a second modification example of the second embodiment, a configuration can be adopted in which the conductive paste is used as the joining material, and an inkjet printer in the previous process or an inkjet printing section provided in component mounter 1 prints the conductive paste on board K using the injection nozzle. Various other applications or modifications can be made for the first to fourth embodiments.

### INDUSTRIAL APPLICABILITY

The configuration of component mounter 1 described in the first to fourth embodiments is not limited to a model that joins component P to board K on which the circuit pattern is formed, and can be used for a joining work machine or an assembling machine that joins components having various materials and various shapes to various workpieces.

### REFERENCE SIGNS LIST

1: component mounter, 2: board conveyance device, 3: component supply device, 31: tape feeder, 35: resin material supply section, 4: component transfer joining device, 40: horizontal drive mechanism, 43: mounting head, 431: Z-axis drive mechanism, 432: setting section, 44: nozzle tool, 443: nozzle holder, 444: elastic body, 45: suction nozzle, 5, 5A: laser light irradiation section, 52: optical switching mechanism, 53: laser light source, 54, 54A: reflection mirror, AP: lifting-and-lowering enabled position, AV: vertical central axis, LL: laser light, K: board, KF: contact surface, P: component, S: joining material

1. A joining work machine comprising:
a work head including a component mounting tool configured to pick up a component and mount the component on a workpiece by being lifted and lowered along a lifting-and-lowering axis, the work head being configured to be driven in a horizontal direction by a horizontal drive mechanism; and
a laser light irradiation section provided in the work head or the horizontal drive mechanism and configured to apply laser light for heating a joining material that generates a predetermined joining force by being applied to at least one of contact surfaces of the component and the workpiece that are in contact with each other and being heated, toward any one of the joining material, the component, and the workpiece from a direction inclined with respect to the lifting-and-lowering axis.

2. The joining work machine according to claim 1,
wherein the work head includes multiple component mounting tools, and
the laser light irradiation section is provided in common to the multiple component mounting tools.

3. The joining work machine according to claim 2,
wherein the work head includes the multiple component mounting tools configured to revolve around a vertical central axis and has the lifting-and-lowering axis set at one or more positions of a revolution trajectory of the component mounting tool, and
the laser light irradiation section is provided in common to the multiple component mounting tools configured to selectively enter a position of the lifting-and-lowering axis.

4. The joining work machine according to claim 1, wherein the laser light irradiation section applies the laser light at a timing including a time period during which the component mounting tool brings the component into contact with the workpiece.

5. The joining work machine according to claim 4, further comprising:
a setting section configured to set a pressing force of the component mounting tool when the component mounting tool presses the component against the workpiece,
wherein the laser light irradiation section applies the laser light in a state where the component mounting tool presses the component against the workpiece with the pressing force set by the setting section.

6. The joining work machine according to claim 5,
wherein the component mounting tool is attached to the work head via an elastic body and presses the component against the workpiece with the pressing force generated by compression of the elastic body.

7. The joining work machine according to claim 4, wherein the laser light irradiation section indirectly heats the joining material via the component by applying the laser light toward the component.

8. The joining work machine according to claim 1, wherein the laser light irradiation section applies the laser light in a time period before the component mounting tool brings the component into contact with the workpiece.

9. The joining work machine according to claim 8,
wherein the laser light irradiation section accumulates a heat quantity in the component by applying the laser light toward the component, and
the joining material applied to the contact surface of the workpiece is heated with the heat quantity accumulated in the component after the component mounting tool brings the component into contact with the workpiece.

10. The joining work machine according to claim 1, wherein the laser light irradiation section includes a laser light source configured to emit the laser light in a direction parallel to the lifting-and-lowering axis, and an optical member configured to reflect or refract the emitted laser light in a direction inclined with respect to the lifting-and-lowering axis.

11. The joining work machine according to claim 1, wherein multiple laser light irradiation sections are provided for one lifting-and-lowering axis.

12. The joining work machine according to claim 1, wherein the laser light irradiation section includes an optical switching mechanism configured to switch an irradiation position at which the laser light is applied.

13. The joining work machine according to claim 12, wherein the irradiation position includes two or more positions among a position of the component held by the component mounting tool, a position of the component in contact with the workpiece, a position of the joining material applied to the contact surface of the workpiece, and a position of the contact surface of the workpiece.

14. The joining work machine according to claim 10, wherein the laser light irradiation section includes an optical switching mechanism configured to switch an irradiation position at which the laser light is applied, and
the optical switching mechanism switches the irradiation position by changing a position of at least one of the laser light source and the optical member with respect to the work head.

15. The joining work machine according to claim 12, wherein the optical switching mechanism also has a function of finely adjusting the irradiation position in accordance with a difference in a type of the component or the workpiece or in accordance with a shape error of the component or the workpiece.

16. The joining work machine according to claim 1,
wherein the component constitutes an electronic circuit,
the workpiece is a board on which a circuit pattern of the electronic circuit is formed, and
the joining material is any one of a non-conductive resin material or adhesive, a conductive solder, or a conductive paste.
